(19) United States
(12) Patent Application Publication
(10) Pub. No.: US 2017/0018602 A1
(43) Pub. Date: Jan. 19, 2017

(54) ORGANIC LIGHT EMITTING DEVICE

(71) Applicant: Samsung Display Co., Ltd., Yongin-si (KR)

(72) Inventors: Young Nam YUN, Suwon-si (KR); Jung-Mi JANG, Anyang-si (KR); Kyu Seok KIM, Asan-si (KR)

(21) Appl. No.: 15/065,350

(22) Filed: Mar. 9, 2016

(30) Foreign Application Priority Data
Jul. 17, 2015 (KR) 10-2015-0101670

(51) Int. Cl. H01L 27/32; H01L 51/52

(52) U.S. Cl. CPC H01L 27/3246; H01L 27/3211; H01L 51/5281; H01L 27/3276; H01L 27/3262; H01L 27/3265; H01L 27/3248; H01L 27/124

(57) ABSTRACT

An organic light emitting display device including: a plurality of pixel electrodes disposed on a substrate; pixel defining layers provided on the plurality of pixel electrodes, and including a plurality of openings respectively exposing the pixel electrodes; and a plurality of organic emission layers respectively formed on the plurality of pixel electrodes. The pixel defining layer includes a resin, and light transmittance of the resin is in a range of about 15% to about 50% with respect to light of a wavelength range of about 380 nm to about 780 nm.

### CROSS-REFERENCE TO RELATED APPLICATION

This application claims priority from and the benefit of Korean Patent Application No. 10-2015-0101670, filed on Jul. 17, 2015, which is hereby incorporated by reference for all purposes as if fully set forth herein.

### BACKGROUND

Field

Exemplary embodiments relate to an organic light emitting device.

Discussion of the Background

In general, an organic light emitting device includes an organic light emitting element formed by laying a first electrode, an organic emission layer, and a second electrode. One of the first electrode and the second electrode is formed of a reflective electrode, and the other is formed of a transmissive electrode such that light of the organic emission layer is collected in a direction of the transmissive electrode and then emitted to the outside. In this case, the transmissive electrode is formed with a structure where a transparent conductive layer and a metal layer are layered such that light partially resonates, thereby improving color reproducibility.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an organic light emitting display that can enhance color sense and, more particularly, a red color sense, and can reduce reflectance of external light to assure excellent visual characteristics.

Additional aspects will be set forth in the detailed description which follows, and, in part, will be apparent from the disclosure, or may be learned by practice of the inventive concept.

An exemplary embodiment discloses an organic light emitting display device includes: a plurality of pixel electrodes disposed on a substrate; pixel defining layers provided on the plurality of pixel electrodes, and including a plurality of openings respectively exposing the pixel electrodes; and a plurality of organic emission layers respectively formed on the plurality of pixel electrodes. The pixel defining layer includes a resin, and light transmittance of the resin is in a range of about 15% to about 50% with respect to light in a wavelength range of about 380 nm to about 780 nm.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is an equivalent circuit diagram of an organic light emitting display device according to an exemplary embodiment.

FIG. 2 is a layout view of a pixel of the organic light emitting display device according to the exemplary embodiment.

FIG. 3 is a cross-sectional view of the organic light emitting display device of FIG. 2, taken along the line III-III in FIG. 2.

FIG. 4 is a graph describing the occurrence of color shift when the display device is viewed from the side.

FIG. 5 exemplarily illustrates coordinates of u′ and v′ according to the CIE 1976 standard protocol.

FIG. 6, FIG. 7, and FIG. 8 are cross-sectional views of the organic light emitting device according to an exemplary embodiment.

FIG. 9A, FIG. 9B, FIG. 9C, and FIG. 9D illustrate a method for manufacturing the organic light emitting display device according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

In the accompanying drawings, an active matrix (AM) type of organic light emitting diode (OLED) display is illustrated to have a 2Tr-1Cap structure in which two transistors (TFTs) and one capacitor are provided for one pixel, but the present disclosure is not limited thereto. Thus, in the OLED display, each pixel may be provided with a plurality of transistors and at least one capacitor, and may be formed to have various structures by further forming additional wires or omitting existing wires. In this case, the pixel is a minimum unit for displaying an image, and the OLED display displays the image through a plurality of pixels.

Hereinafter, the present disclosure will be described in detail with reference to the accompanying drawings.

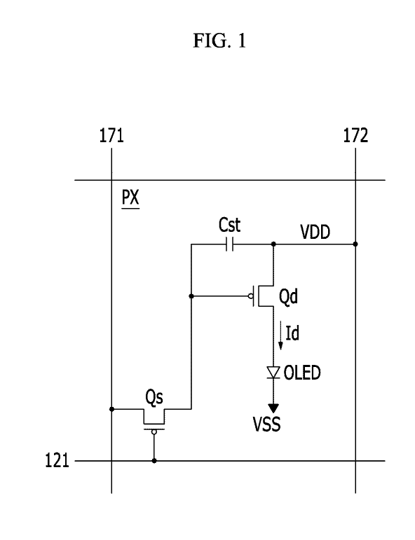

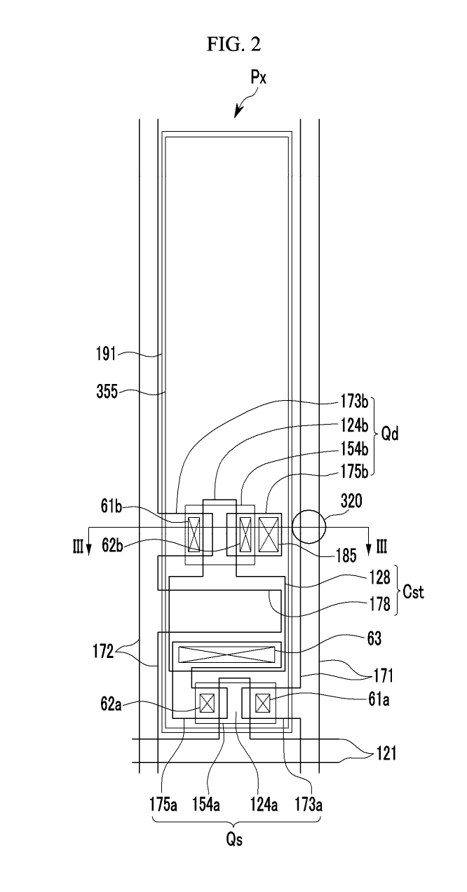

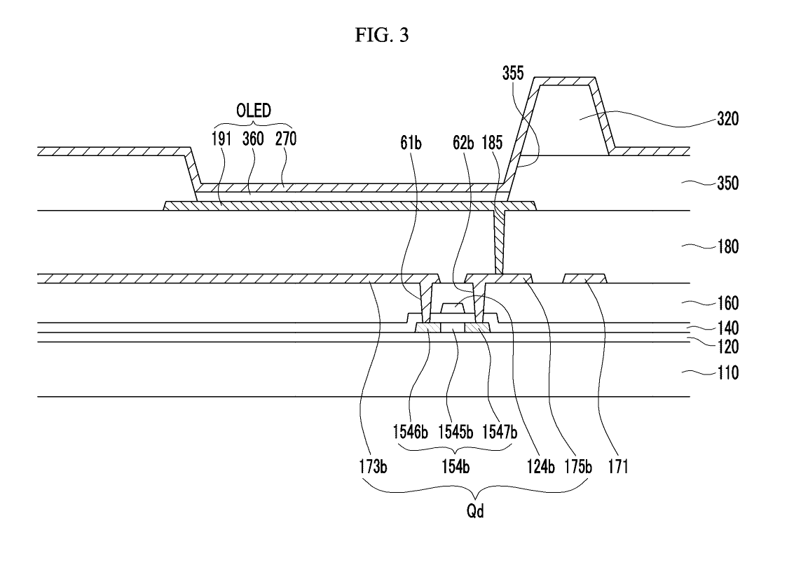

FIG. 1 is an equivalent circuit diagram of a pixel of an organic light emitting display device according to an exemplary embodiment; FIG. 2 is a layout view of a pixel of the organic light emitting display device according to the exemplary embodiment; and FIG. 3 is a cross-sectional view of the organic light emitting display device of FIG. 2, taken along the line III-III.

First, referring to FIG. 1, an organic light emitting display device according to an exemplary embodiment includes a plurality of signal lines 121, 171, and 172, and pixels connected to the signal lines 121, 171, and 172 and arranged substantially in a matrix format.

In this case, the signal lines include gate lines 121 transmitting a gate signal (or a scan signal); data lines 171 transmitting a data signal; and driving voltage lines 172 transmitting a driving voltage VDD. Further, the gate lines 121 extend substantially in a row direction and are substantially parallel to each other, and the data lines 171 and the driving voltage lines 172 substantially extend in a column direction and are substantially parallel to each other.

Each pixel PX includes a switching thin film transistor Qs, a driving thin film transistor Qd, a storage capacitor Cst, and an organic light emitting diode OLED.

First, the switching thin film transistor Qs includes a control terminal, an input terminal, and an output terminal, and the control terminal is connected to the gate line 121, the input terminal is connected to the data line 171, and the output terminal is connected to the driving thin film transistor Qd. Further, the switching thin film transistor Qs transmits a data signal applied to the data line 171 to the driving thin film transistor Qd in response to a gate signal applied to the gate line 121.

The driving thin film transistor Qd also includes a control terminal, an input terminal, and an output terminal, and the control terminal is connected to the switching thin film transistor Qs; the input terminal is connected to the driving voltage line 172; and the output terminal is connected to the organic light emitting diode OLED. The driving thin film transistor Qd outputs an output current Id, the magnitude of which varies according to a voltage applied between the control terminal and the output terminal.

The storage capacitor Cst is connected between the control terminal and the input terminal of the driving thin film transistor Qd. In this case, the storage capacitor Cst is charged by a data signal applied to the control terminal of the driving thin film transistor Qd, and maintains the charge of the data signal after the switching thin film transistor Qs is turned off.

The organic light emitting diode OLED includes an anode connected to the output terminal of the driving thin film transistor Qd and a cathode connected to a common voltage VSS. Here, the organic light emitting diode OLED displays an image by emitting light, the strength of which varies depending on a current of the driving thin film transistor Qd.

The switching thin film transistor Qs and the driving thin film transistor Qd may be n-channel field effect transistors (FET) or p-channel field effect transistors. Further, a connection relationship between the switching and driving thin film transistors Qs and Qd, the storage capacitor Cst, and the organic light emitting diode OLED can be changed.

Referring to FIG. 2 and FIG. 3, the organic light emitting display device according to the exemplary embodiment includes a plurality of thin film structures disposed on a substrate 110.

The substrate 110 may be made of a rigid material such as glass, metal, or synthetic resin, or may be made of a flexible material such as polyimide (PI), polyethylene terephthalate (PET), polyethersulfone (PES), polyacrylate (PAR), polyetherimide (PEI), polyethylene naphthalate (PEN), polyethylene terephthalate (PET), polyphenylene sulfide (PPS), polyarylate (PA), or triacetyl cellulose (TAC), but this is not restrictive. That is, the substrate 110 according to the exemplary embodiment is not limited by various physical properties such as a type, a property, and a material.

In addition, a buffer layer 120, serving to prevent permeation of an impurity element and planarize the surface, may be provided on the substrate 110.

The buffer layer 120 may be made of various materials that can perform the above-stated functions, and may be formed of a singular layer or a multilayer of at least two layers. The buffer layer 120 may be made of, for example, one of a silicon nitride (SiNₓ) layer, a silicon oxide (SiO_{y}) layer, and a silicon oxynitride (SiOₓNy) layer, but is not limited thereto. Although the buffer layer 120 according to the exemplary embodiment is a prerequisite constituent element, the buffer layer 120 may be omitted according to the type of the display substrate and process conditions.

A switching semiconductor layer 154a and a driving semiconductor layer 154b are disposed at a distance from each other on the buffer layer 120. In this case, the switching semiconductor layer 154a and the driving semiconductor layer 154b have similar interlayer configurations, and therefore the driving semiconductor layer 154b will be described with reference to FIG. 3.

The driving semiconductor layer 154b may be made of polycrystalline silicon. Further, the driving semiconductor layer 154b includes a driving channel region 1545b, a driving source region 1546b, and a driving drain region 1547b. The driving source region 1546b and the driving drain region 1547b are disposed at lateral sides of the driving channel region 1545b.

The driving channel region 1545b may be polycrystalline silicon not doped with an impurity, that is, an intrinsic semiconductor, and the driving source region 1546b and the driving drain region 1547b may be crystalline silicon doped with an impurity, that is, impurity semiconductors.

A gate insulating layer 140 is disposed on the buffer layer 120 and the driving semiconductor layer 154b. The gate insulating layer 140 may include at least one of tetraethyl orthosilicate (TEOS), a silicon nitride, and a silicon oxide, and may be formed of a single layer or a multiple layer.

A gate electrode 124b is formed on the driving semiconductor layer 154b, and the gate electrode 124b overlaps the driving channel region 1545b.

In this case, the gate electrode 124b may be formed of a single layer or a multiple layer using a low resistance material such as Al, Ti, Mo, Cu, Ni, or an alloy thereof, or a material having low resistance to corrosion.

An interlayer insulating layer 160 is formed on the gate electrode 124b. Like the gate insulating layer 140, the interlayer insulating layer 160 may be formed of a single layer or a plurality of layers of tetraethyl orthosilicate (TEOS), a silicon nitride, and a silicon oxide.

A source contact hole 6 lb and a drain contact hole 62b respectively exposing the driving source region 1546b and the driving drain region 1547b are formed in the interlayer insulating layer 160 and the gate insulating layer 140.

The data line 171, a source electrode 173b, and a drain electrode 175b are disposed on the interlayer insulating layer 160. The data line 171 transmits a data signal and extends in a direction that crosses the gate line 121, and includes a switching source electrode 173a protruding toward the switching semiconductor layer 154a from the data line 171.

The source electrode 173b is connected with the source region 1546b through a contact hole 61b, and the drain electrode 175b is connected with the drain region 1547b through a contact hole 62b.

The source electrode 173b and the drain electrode 175b may be formed of a single layer or a multiple layer using a low resistance material such as Al, Ti, Mo, Cu, Ni, or an alloy thereof, or a material having high corrosion resistance. For example, the source electrode 173b and the drain electrode 175b may be a triple layer of Ti/Cu/Ti, Ti/Ag/Ti, or Mo/Al/Mo.

The driving semiconductor layer 154b, the gate electrode 124b, the source electrode 173b, and the drain electrode 175b form the driving thin film transistor Qd.

A planarization layer 180 is formed on the source electrode 173b and the drain electrode 175b.

In this case, the planarization layer 180 may be made of one or more materials of a polyacrylate resin, an epoxy resin, a phenolic resin, a polyamide resin, a polyimide resin, an unsaturated polyester resin, a poly(phenylene ether) resin, a poly(phenylene sulfide) resin, and benzocyclobutene (BCB).

The planarization layer 180 may have a flat surface by removing a step in order to increase light emission efficiency of an organic light emitting element to be formed thereon. The planarization layer 180 includes a contact hole 185 exposing the drain electrode 175b.

The organic light emitting display device according to the exemplary embodiment is not limited to the above-stated structure, and one of the planarization layer 180 and the interlayer insulating layer 160 may be omitted.

The organic light emitting diode OLED and a pixel defining layer 350 are disposed on the planarization layer 180.

In this case, the organic light emitting diode OLED includes a pixel electrode 191, an organic emission layer 360, and a common electrode 270. In the exemplary embodiment, a plurality of pixel electrodes 191 and a plurality of common electrodes 270 may be provided, and one of the pixel electrode 191 and the common electrode 270 may be an anode serving as a hole injection electrode, while the other may be a cathode serving as an electron injection electrode.

The pixel electrode 191 is disposed on the planarization layer 180, and is electrically and physically connected with the drain electrode 175b of the driving thin film transistor Qd through the contact hole 185 formed in the planarization layer 180. That is, the pixel electrode 191 receives an electrical signal from the drain electrode 175b and transmits electrons or holes to the organic emission layer 360 such that the organic light emitting display device can be operated. Thus, the organic light emitting display device according to the exemplary embodiment includes a plurality of pixel electrodes 191 respectively disposed in the plurality of pixels PX. In this case, the plurality of pixel electrodes 191 are spaced apart from each other.

The pixel defining layer 350 may be disposed on the planarization layer 180 where an opening that exposes the pixel electrode 191 is formed. That is, a plurality of openings that respectively correspond to the pixels are formed between the pixel defining layers 350, and the openings of the pixel defining layers 350 respectively exposing the pixel electrodes 191 may define respective pixel PX areas.

In this case, the pixel electrodes 191 are disposed to correspond to the openings of the respective pixel defining layers 350. However, the pixel electrode 191 is not necessarily disposed in the opening of the pixel defining layer 350, and as shown in FIG. 3, the pixel electrode 191 may be disposed below the pixel defining layer 350 such that a part of the pixel electrode may overlap the pixel defining layer 350.

In the exemplary embodiment, each pixel defining layer 350 may include a resin. The resin may have light transmittance of about 15% to about 50% with respect to light in a wavelength range of about 380 nm to about 780 nm. Particularly, the resin may have light transmittance of about 15% to about 50% with respect to light in a wavelength range of about 560 nm to about 780 nm.

In general, in an organic light emitting display device that adopts a resonance structure, when a viewer moves to a side from a front of the display device, thereby increasing a viewing angle, a color shift may occurs such that a given color is partially viewed as a different color rather than its original color. This is because a resonance condition of light is changed according to a viewing angle. Thus, even though a vivid full color screen is implemented at the front of the organic light emitting display device, a color shift occurs in a color emitted from a spot in a side of a display device having a relative large viewing angle that results in a change to another color, thereby causing deterioration of image quality.

Particularly, in case of a red color having a relatively narrow bandwidth compared to another color in a visible region, a vivid red color cannot be realized because a color shift may occur to a short wavelength and, thus, light emitted as a vivid red color at a front of the display device may be viewed as an orange color in a side of the display device.

However, as described in the present exemplary embodiment, the pixel defining layer is made of a resin having light transmittance of about 15% to about 50% with respect to light in a wavelength range of about 380 nm to about 780 nm and, thus, the spectrum of a short wavelength side among the red spectrum emitted in the side direction of the display device is absorbed to prevent the color sense of the red color from being color-shifted to an orange color, thereby realizing a vivid red color.

The organic emission layer 360 and the common electrode 270 are sequentially layered in an upper portion of the pixel defining layer 350, and the pixel defining layer 350 absorbs more than half of external light incident on the display device so that the amount of light reflected to the common electrode 270, which effectively serves as unwanted noise, can be significantly reduced. That is, the surface reflectance of external light incident on the display device can be remarkably reduced.

Light transmittance of light of the resin may be about 15% to about 50% with respect to light of a wavelength range of about 560 nm to about 780 nm.

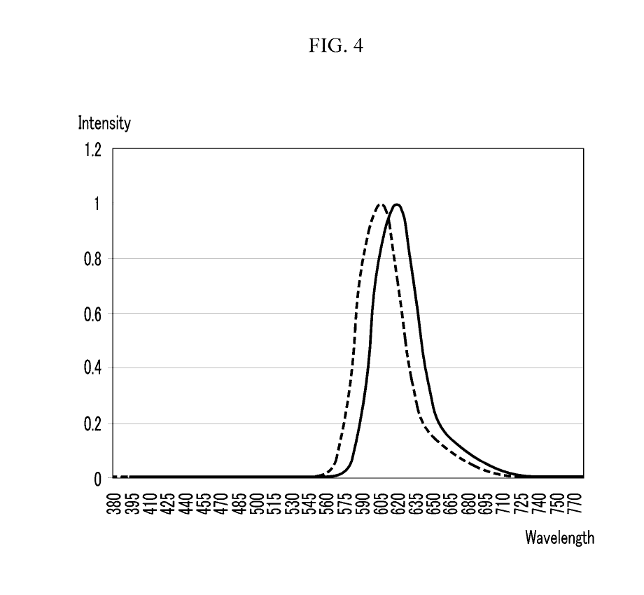

FIG. 4 illustrates a wavelength curve of a red color viewed in a side direction of the display device.

Referring to FIG. 4, in the graph, the solid-lined spectrum denotes the spectrum of a red color emitted from the front of the display device. However, the red color spectrum is shifted to a short wavelength range, as shown by the dotted line in the side of the display device.

When the pixel defining layer is formed using a resin having light transmittance of about 15% to 50% in a visible ray region, specifically in a long wavelength area, the spectrum of a short wavelength area among spectrum of a red color emitted from a side of the display device is absorbed so that color sense of the viewed red color can be prevented in advance from being shifted to an orange color.

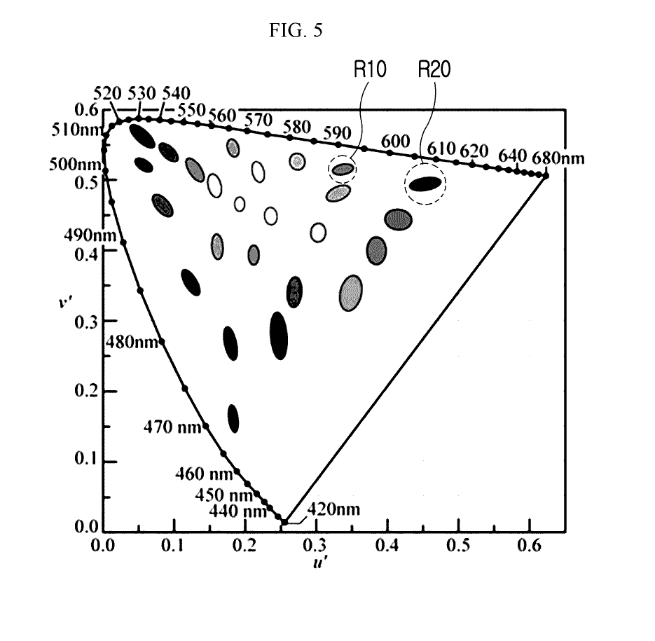

The organic light emitting display device according to the exemplary embodiment, for comprehension of reinforcement of color sense of a red color, u′ and v′ coordinates according to the CIE 1976 standard protocol are exemplarily illustrated in FIG. 5. Referring to FIG. 5, according to the color coordinate distribution of the red color measured in the side of the organic light emitting display device according to the exemplary embodiment, distribution in the R10 area of the color coordinate system is reduced and distribution in the R20 area of the color coordinate system is increased so that a more vivid red color can be realized.

If necessary, the pixel defining layer according to the present invention may further include a blue dye. In general, the blue dye has a wavelength of less than or equal to about 500 nm, and more specifically, has a wavelength of less than or equal to about 450 nm and light transmittance of less than or equal to about 10%. Therefore, reflection of external light can be reduced by a factor of three or more as compared to a case of forming the pixel defining layer by using only a resin having light transmittance of about 380 nm to about 780 nm. Thus, the organic light emitting display device according to the exemplary embodiment can provide higher image quality.

Next, the organic emission layer 360 may be provided on the pixel electrode 191 disposed in an opening 355 of the pixel defining layer 350.

In this case, the organic emission layer 360 may be formed of multiple layers including one or more of an emission layer, a hole-injecting layer (HIL), a hole transporting layer (HTL), an electron-transporting layer (ETL), and an electron-injecting layer (EIL). When the organic emission layer 360 includes all of these layers, the hole injecting layer may be provided on the pixel electrode 191, which is an anode, and the hole transporting layer, the emission layer, the electron transporting layer, and the electron injecting layer may be sequentially layered thereon. Further, the organic emission layer 360 may be made of a low-molecular material or a high-molecular material such as poly(3,4-ethylenedioxythiophene) (PEDOT) and the like.

The organic emission layer 360 may be at least one of a red organic emission layer emitting light of red, a blue organic emission layer emitting light of blue, and a green organic emission layer emitting light of green. In this case, the red organic emission layer, the blue organic emission layer, and the green organic emission layer are respectively formed in a red pixel, a green pixel, and a blue pixel to realize a color image.

Such an organic emission layer 360 may be formed through a printing process, such as inkjet printing or nozzle printing, or may be formed using a mask, but the present invention is not so limited.

Optionally, in the organic emission layer 360, all of the red organic emission layer, the green organic emission layer, and the blue organic emission layer may be laminated together on the red pixel, the green pixel, and the blue pixel, and a red color filter, a green color filter, and a blue color filter are formed for each pixel, thereby implementing the color image.

As another example, as the organic emission layer 360, white organic emission layers emitting white light are formed in all of the red pixel, the green pixel, and the blue pixel, and a red color filter, a green color filter, and a blue color filter are formed for each pixel, thereby implementing the color image. In the case of implementing the color image by using the white organic emission layer as the organic emission layer 360 and the color filters, the use of a deposition mask is not required for depositing the red organic emission layer, the green organic emission layer, and the blue organic emission layer on respective pixels, that is, the red pixel, the green pixel, and the blue pixel.

The white organic emission layer described in another example may be formed by one organic emission layer, and also includes a configuration formed so as to emit white light by laminating a plurality of organic emission layers. For example, a configuration which may emit white light by combining at least one yellow organic emission layer and at least one blue light emitting layer, a configuration which may emit white light by combining at least one cyan organic emission layer and at least one red light emitting layer, a configuration which may emit white light by combining at least one magenta organic emission layer and at least one green light emitting layer, and the like may be included, but this is not restrictive.

The common electrode 270 may be disposed on the organic emission layer 360. As such, the organic light emitting diode OLED including the pixel electrode 191, the organic emission layer 360, and the common electrode 270 is formed.

In this case, the pixel electrode 191 and the common electrode 270 may be respectively formed of a transparent conductive material, or a transflective or reflective conductive material. Particularly, as a reflective conductive material, for example, lithium (Li), calcium (Ca), lithium fluoride/calcium (LiF/Ca), lithium fluoride/aluminum (LiF/Al), aluminum (Al), silver (Ag), magnesium (Mg), or gold (Au) may be used. According to the type of materials forming the pixel electrode 191 and the common electrode 270, the organic light emitting display device may be a top emission type, a bottom emission type, or a double-sided emission type.

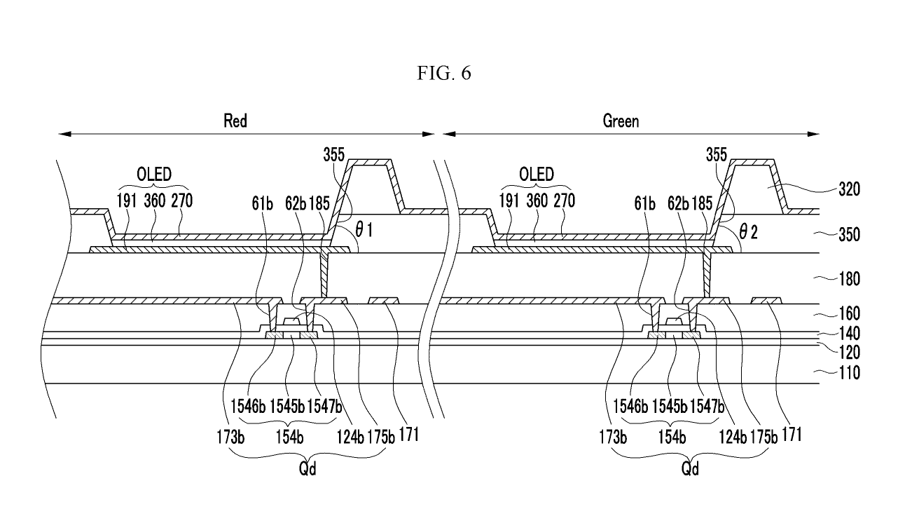

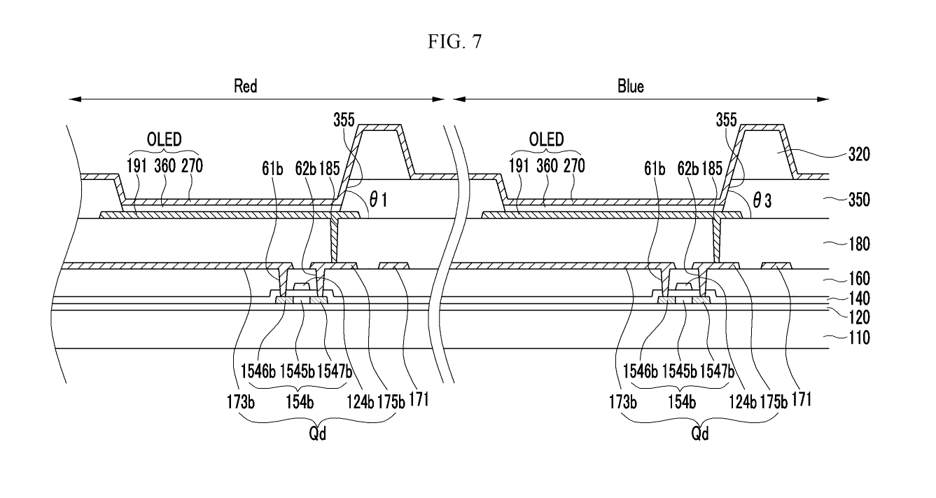

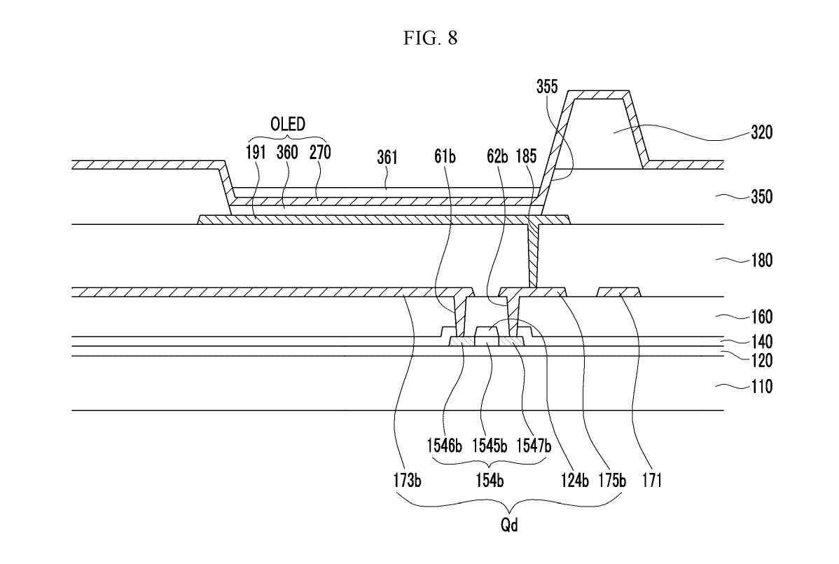

FIG. 6 illustrates a cross-sectional view of the organic light emitting display device according to an exemplary embodiment.

As shown in FIG. 6, as necessary, an assistant organic thin film 361 may be disposed on a common electrode 270 of a red organic emission layer. In this case, the assistant organic thin film 361 may have a thickness of less than or equal to about 1 μm.

In addition, the assistant organic thin film 361 may be formed of a resin having light transmittance of about 15% to about 50% with respect to light of a wavelength range of about 560 nm to about 780 nm.

As described, when an assistant organic thin film formed using a resin of which light transmittance with respect to light of the red wavelength range satisfies the above range is additionally disposed on the common electrode 270, the spectrum of light emitting in a red pixel may be color-shifted to a longer wavelength area. Thus, a deeper red can be realized so that red color sense can be more excellently reinforced in the front view of the display device. That is, the organic light emitting display according to the exemplary embodiment can improve color sense of a red color in the front view and at the same time absorb the short-wavelength spectrum area that represents an orange color in a red color emitted to the side through the pixel defining layer so that the color sense of the red color can be more effectively reinforced.

FIG. 7 and FIG. 8 respectively illustrate cross-sectional views of the organic light emitting display according to an exemplary embodiment.

Referring to FIG. 7 and FIG. 8, in the organic light emitting display device according to the exemplary embodiment, a taper angle θ1 of the pixel defining layer 350 located adjacent to the red organic emission layer may be greater than taper angles θ2 and θ3 of the pixel defining layer 350 located adjacent to the green and/or blue organic emission layer.

More specifically, the taper angle θ1 of the pixel defining layer 350 located adjacent to the red organic emission layer may be 1.1 to 2 times greater than the taper angles θ2 and θ3 of the pixel defining layer 350 located adjacent to the blue and/or green organic emission layer. In this case, the taper angles θ2 and θ3 of the pixel defining layer 350 located adjacent to the blue and/or green organic emission layer may be 10 degrees to 90 degrees, but the present invention is not so limited.

In the present exemplary embodiment, the taper angle of the pixel defining layer 350 implies an angle formed by the planarization layer 180 and the opening 355 of the pixel defining layer 350 as shown in FIG. 7 and FIG. 8.

As described above, when the taper angle θ1 of the pixel defining layer 350 located adjacent to the red organic emission layer is greater than the taper angles θ2 and θ3 of the pixel defining layer 350 located adjacent to the green and/or blue organic emission layer 350, light of an orange color emitted from the red organic emission layer may be prevented from being emitted to the outside of the display device. Accordingly, luminance of light of the orange color emitted in a side direction of the display device can be reduced, thereby remarkably reducing occurrence of a case that a red color is viewed as an orange color in the side view.

In some cases, a spacer 320 may be disposed on the pixel defining layer 350. Such a spacer 320 may be made of the same material as the pixel defining layer 350. When the spacer 320 and the pixel defining layer 350 are made of the same material, the spacer can be formed using the same mask in a process for forming the pixel defining layer, thereby simplifying the process.

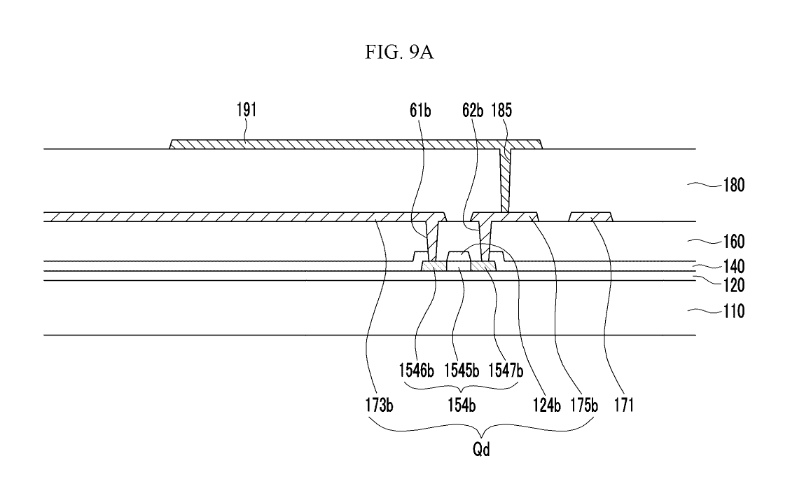

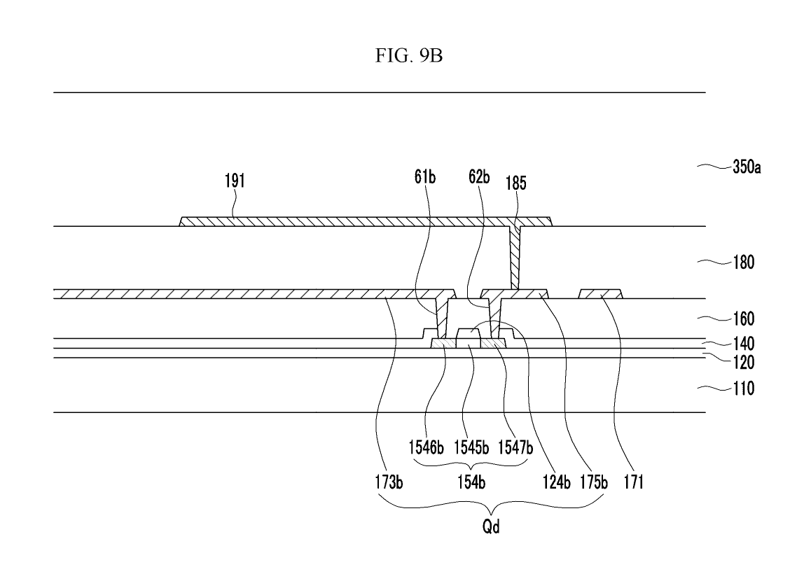

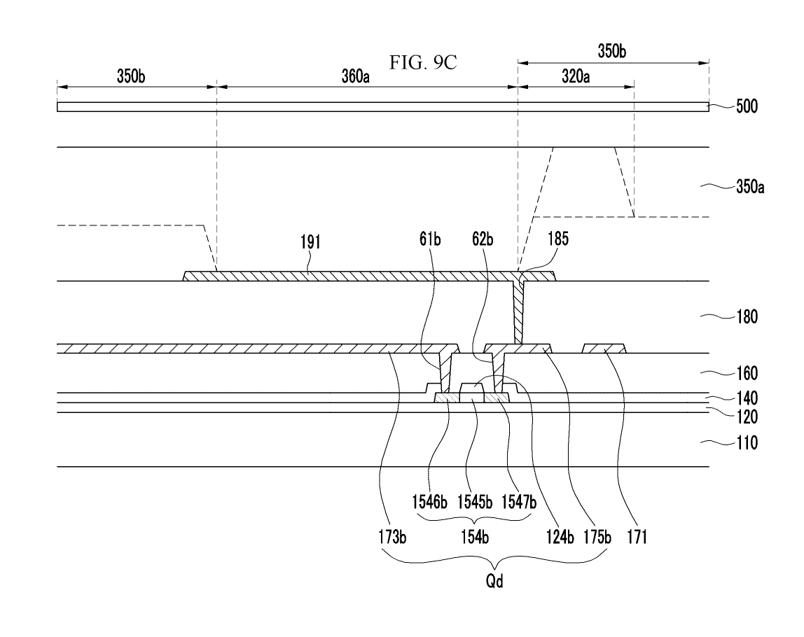

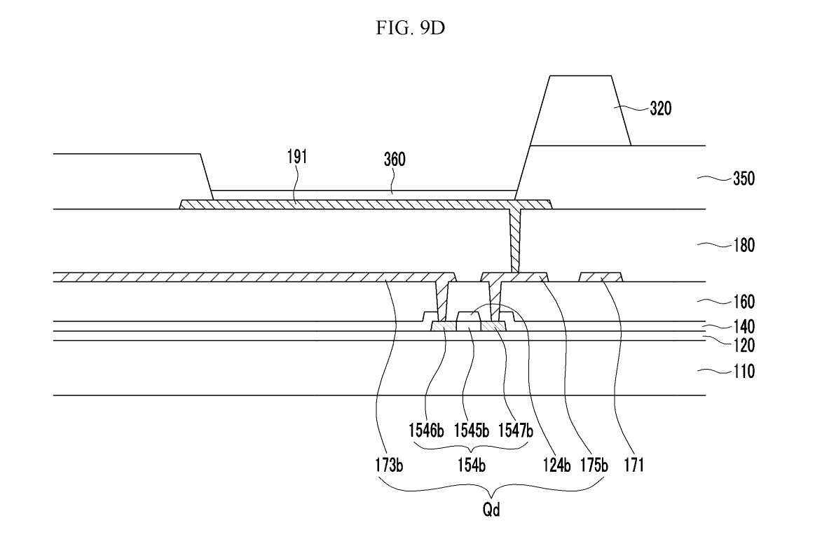

For better understanding, FIG. 9A to FIG. 9D exemplarily illustrate a method for manufacturing the organic light emitting display device according to an exemplary embodiment.

First, as shown in FIG. 9A, the planarization layer 180 is formed on the substrate 110 where the driving thin film transistor Qd is formed and the plurality of pixel electrodes 191 are formed.

Next, as described above, as shown in FIG. 9B, a resin layer 350a is formed using a resin of which light transmittance is about 15% to about 50% with respect to light of a wavelength range of about 380 nm to about 780 nm.

A mask 500 (see FIG. 9C) is disposed on the resin layer 350a. In this case, the mask 500 includes an area 350b for patterning the pixel defining layer. Further, when the spacer is formed together with the pixel defining layer, as shown in FIG. 9C, an area 320a for patterning the spacer may be included in the area 350b provided for patterning the pixel defining layer.

Next, the pixel defining layer 350 and the spacer 320 are disposed through the exposure and etching process. In this case, the pixel defining layer 350 and the spacer 320 may be formed using one mask in the same process by using a method that differently controls exposure time of the area 350b provided for patterning the pixel defining layer 350 and exposure time of the area 320a provided for patterning the spacer 320.

Next, as shown in FIG. 9D, the organic emission layer 360 is formed, and then the common electrode layer 270 is formed to cover all of the pixel defining layer 350, the spacer 320, and the organic emission layer 360 such that the organic light emitting display device having the structure of FIG. 3 can be manufactured.

An encapsulation substrate (not shown) may be disposed on the spacer 320. The encapsulation substrate and the substrate 110 are bonded to each other by a sealant (not shown). In this case, the spacer 320 maintains a gap between the substrate 110 and the encapsulation substrate.

Further, a polarization film (not shown) may be disposed on the encapsulation substrate. The polarization film converts an optical axial of light emitted to the outside through an organic light emitting diode. Generally, the polarization film has a structure in which transparent protective films are laminated on both sides or one side of a polarizer made of a polyvinyl alcohol-based resin.

In more detail, the polarization film is formed as a structure in which a triacetyl cellulose (TAC) film as a protective film is adhered to a polarizer having a structure in which polyvinyl alcohol (hereinafter referred to as PVA)-based molecular chains are aligned in a predetermined direction and an iodine-based compound or a dichroic polarizing material is included. Further, the polarizer and the protective film are generally adhered to each other by a water-based adhesive made of a polyvinyl alcohol-based solution. However, in the present invention, the polarization film is not limited thereto, and polarization films formed of various structures and materials may be used.

According to exemplary embodiments, vivid image quality can be realized not only in the front view but also in the side view of the display device by enhancing a red color sense. An excellent contrast ratio can also be obtained by reducing surface reflectance of external light incident on the display device so that exemplary embodiments of the organic light emitting display device can provided excellent visual sense characteristics.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An organic light emitting display device comprising:
a plurality of pixel electrodes disposed on a substrate;
pixel defining layers disposed on the plurality of pixel electrodes, the pixel defining layers comprising a plurality of openings respectively exposing the pixel electrodes; and
a plurality of organic emission layers respectively disposed on the plurality of pixel electrodes,
wherein:
the pixel defining layer comprises a resin; and
light transmittance of the resin is in a range of about 15% to about 50% with respect to light of a wavelength range of about 380 nm to about 780 nm.

2. The organic light emitting display device of claim 1, wherein light transmittance of the resin is in a range of about 15% to 50% with respect to light of a wavelength range of about 560 nm to about 780 nm.

3. The organic light emitting display device of claim 1, wherein the plurality of organic emission layers emit light of at least one of red, blue, and green.

4. The organic light emitting display device of claim 3, wherein a taper angle of a pixel defining layer disposed adjacent to a red organic emission layer is greater than a taper angle of a pixel defining layer disposed adjacent to a green organic emission layer.

5. The organic light emitting display device of claim 3, wherein a taper angle of a pixel defining layer disposed adjacent to a red organic emission layer is greater than a taper angle of a pixel defining layer disposed adjacent to a blue organic emission layer.

6. The organic light emitting display device of claim 3, further comprising an assistant organic thin film disposed on the red organic emission layer.

7. The organic light emitting display device of claim 6, wherein the thickness of the assistant organic thin film is less than or equal to 1 μm.

8. The organic light emitting display device of claim 6, wherein the assistant organic thin film is formed using a resin of which light transmittance is in a range of about 15% to about 50% with respect to light of a wavelength range of about 560 nm to about 780 nm.

9. The organic light emitting display device of claim 1, wherein the pixel defining layer further comprises a blue dye.

10. The organic light emitting display device of claim 1, further comprising a spacer provided on the pixel defining layer.

11. The organic light emitting display device of claim 10, wherein the spacer comprises the same material as the pixel defining layer.
